(19) United States
(12) Patent Application Publication
(10) Pub. No.: US 2016/0141250 A1
(43) Pub. Date: May 19, 2016

(54) BARRIER STRUCTURE

(71) Applicant: QUALCOMM Incorporated, San Diego, CA (US)

(72) Inventors: Junjing Bao, San Diego, CA (US); Jeffrey Junhao Xu, San Diego, CA (US); John Jianhong Zhu, San Diego, CA (US); Da Yang, San Diego, CA (US); Stanley Seungchul Song, San Diego, CA (US); Choh Fei Yeap, San Diego, CA (US)

(21) Appl. No.: 14/660,544

(22) Filed: Mar. 17, 2015

Related U.S. Application Data
(60) Provisional application No. 62/080,944, filed on Nov. 17, 2014.

(51) Int. Cl. H01L 23/532; H01L 21/3205; H01L 21/768

(52) U.S. Cl. CPC H01L 23/53238; H01L 21/76807; H01L 21/76843; H01L 21/32051; H01L 21/76864; H01L 21/7684

(57) ABSTRACT

A semiconductor device includes a dielectric material and an interconnect structure. The semiconductor device further includes a barrier layer positioned between the dielectric material and the interconnect structure. The barrier layer includes two or more metals. Each metal of the two or more metals of the barrier layer is phase segregated from each other metal of the two or more metals.

### I. CLAIM OF PRIORITY

The present application claims priority from U.S. Provisional Patent Application No. 62/080,944, entitled “BARRIER STRUCTURE,” filed Nov. 17, 2014, the content of which is incorporated by reference in its entirety.

### II. FIELD

The present disclosure is generally related to a barrier structure.

### III. DESCRIPTION OF RELATED ART

A semiconductor device may include an interconnect structure to electrically couple different layers of the semiconductor device. The interconnect structure typically includes a copper (Cu) structure formed in a dielectric material (e.g., an insulating material). To prevent copper atoms from diffusing into the dielectric material, a barrier layer may be formed between the copper structure and the dielectric material. Typically, a tantalum nitride (TaN)/tantalum (Ta) bi-layer barrier is used as the barrier layer and needs to be more than 2 nanometers (nm) thick to act as an effective barrier. The TaN/Ta barrier may be deposited using a physical vapor deposition (PVD) process that has poor coverage on sidewalls on which the TaN/Ta barrier is deposited. In order to form a layer with a 2 nm thickness of TaN/Ta using the PVD process, an amount of TaN/Ta barrier that forms (e.g., collects) at a bottom of a cavity may be greater than 2 nm thick and may cause the interconnect structure to have a high resistance. As line widths of semiconductor devices are reduced to below 20 nm, the high resistance resulting from the TaN/Ta barrier may increase a resistor-capacitor (RC) delay of a circuit that includes the interconnect structure.

### IV. SUMMARY

The present disclosure describes a semiconductor device that includes an interconnect structure (e.g., a via structure) associated with a barrier layer that includes a composite of two or more metals. For example, each metal of the two or more metals of the barrier layer may be phase segregated (e.g., the two or more metals are separate and not included in an alloy). The barrier layer including the two or more metals may be a single layer. In some implementations, the barrier layer may have a thickness of less than or equal to 2 nanometers (nm). The semiconductor device may include a dielectric material and an interconnect structure (e.g., a copper structure) formed in the dielectric material. The barrier layer (e.g., a barrier structure) may be positioned between the dielectric material and the interconnect structure.

At least one metal of the two or more metals has low solubility (e.g., good wettability) with a conductive material of the interconnect structure. For example, if the conductive material is copper (Cu), the at least one metal may be ruthenium (Ru), as an illustrative, non-limiting example. A first metal of the two or more metals may be a higher percentage of the composite than the other metal(s). The first metal may have a first atomic diameter and each other metal may have a different atomic diameter (e.g., an atomic diameter that is not included within a range between −15% and +15% of the first atomic diameter).

In a particular aspect, a semiconductor device includes a dielectric material and an interconnect structure. The semiconductor device further includes a barrier layer positioned between the dielectric material and the interconnect structure. The barrier layer includes two or more metals. Each metal of the two or more metals of the barrier layer is phase segmented from each other metal of the two or more metals.

In another particular aspect, a method includes forming a cavity in a dielectric layer and forming a barrier layer within the cavity. The barrier layer includes two or more metals. Each metal of the two or more metals of the barrier layer is phase segregated from each other metal of the two or more metals. The method further includes forming an interconnect structure above the barrier layer.

In another particular aspect, a computer-readable storage device stores instructions that, when executed by a processor, cause the processor to perform operations including initiating formation of a cavity in a dielectric layer of a semiconductor device and initiating formation of a barrier layer within the cavity. The barrier layer includes two or more metals. Each metal of the two or more metals is phase segregated from each other metal of the two or more metals. The operations further include initiating formation of an interconnect structure above the barrier layer.

In another particular aspect, an apparatus includes means for resisting diffusion of a conductive material of an interconnect of a semiconductor device into a dielectric layer of the semiconductor device. The means for resisting comprises two or more metals. Each metal of the two or more metals of the barrier layer is phase segregated from each other metal of the two or more metals. The apparatus further includes means for conducting current coupled to the interconnect, wherein the means for resisting diffusion is positioned between the means for conducting and the interconnect.

One particular advantage provided by at least one of the disclosed embodiments is a barrier layer that is ultra-thin (e.g., has a thickness of less than or equal to 2 nm). The barrier layer may resist diffusion of a conductive material (e.g., copper) of an interconnect structures and may have good wettability (e.g., low solubility) with the conductive material.

Other aspects, advantages, and features of the present disclosure will become apparent after review of the entire application, including the following sections: Brief Description of the Drawings, Detailed Description, and the Claims.

### V. BRIEF DESCRIPTION OF THE DRAWINGS

FIG. 1 is a block diagram of a particular illustrative embodiment of a semiconductor device having a barrier layer;

FIG. 2 is a graph to illustrate selection of metals having low solubility with copper;

FIG. 3 is a graph to illustrate selection of metals included in a barrier layer;

FIGS. 4A, 4B, and 4C are diagrams of an illustrative example of a process of fabricating the semiconductor device of FIG. 1;

FIG. 5 is a flow chart of a particular illustrative embodiment of a method of forming the semiconductor device of FIG. 1;

FIG. 6 is a block diagram of an electronic device including the semiconductor device of FIG. 1; and

FIG. 7 is a data flow diagram of a particular illustrative embodiment of a manufacturing process to manufacture electronic devices that include the semiconductor device of FIG. 1.

### VI. DETAILED DESCRIPTION

Particular embodiments of the present disclosure are described below with reference to the drawings. In the description, common features are designated by common reference numbers.

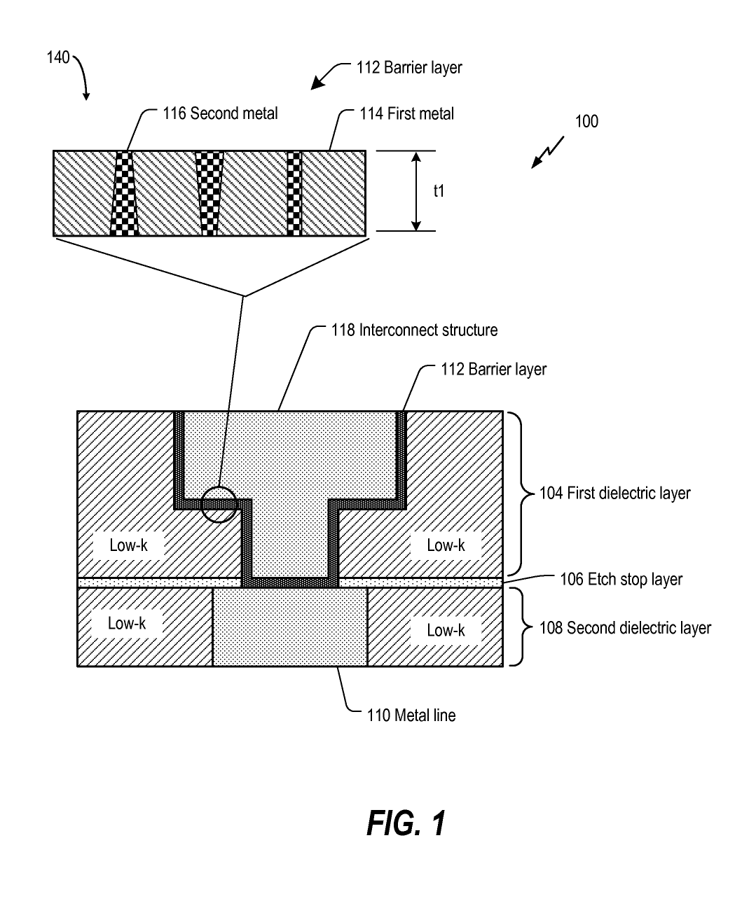

Referring to FIG. 1, a particular illustrative embodiment of a semiconductor device 100 that includes a barrier layer is shown. The semiconductor device 100 may be included in a wafer (not shown) that includes one or more semiconductor devices.

The semiconductor device 100 may include a first dielectric layer 104, an etch stop layer 106, and a second dielectric layer 108. The etch stop layer 106 may be positioned between the first dielectric layer 104 and the second dielectric layer 108. The first dielectric layer 104 and the second dielectric layer 108 may include a dielectric material. For example, the first dielectric layer 104 and/or the second dielectric layer 108 may include a low-k dielectric material, such as a silicon-carbide-based oxide material (SiCOH), a carbon doped oxide material (CDO), or a spin-on, polymer-based low-k dielectric material (e.g., a SiLK™ (trademark of The Dow Chemical Company) material).

The semiconductor device 100 may include an interconnect structure 118 coupled to a metal line 110. The metal line 110 may include a conductive material, such as copper (Cu), tungsten (W), cobalt (Co), or a combination thereof, as illustrative, non-limiting examples. In some implementations, the metal line 110 may include and/or may be in contact with a barrier (not shown) and/or a capping layer (not shown). The barrier (e.g., TaN/Ta, titanium nitride (TiN), or a composite barrier, as described herein) may be positioned between the metal line 110 and the second dielectric layer 108. Additionally or alternatively, the capping layer (e.g., cobalt (Co)) may be positioned between the metal line 110 and the etch stop layer 106 and/or between the metal line 110 and the interconnect structure 118. The metal line 110 may have a width of less than 20 nanometers (nm). For example, the metal line 110 may have a width of less than 18 nm, as an illustrative, non-limiting example. The width of the metal line 110 may include the barrier (e.g., TaN/Ta).

The interconnect structure 118 (e.g., a via structure) may include a conductive material, such as copper (Cu). For example, the interconnect structure 118 may be a coper structure formed in the dielectric material of the first dielectric layer 104. The conductive material of the interconnect structure 118 may be the same as or different from the conductive material of the metal line 110.

The interconnect structure 118 may be associated with (e.g., proximate to) a barrier layer 112 (e.g., a barrier structure). The barrier layer 112 may be positioned between the first dielectric layer 104 and the interconnect structure 118. For example, the barrier layer 112 may be in contact with the first dielectric layer 104 (e.g., a dielectric material of the first dielectric layer 104) and/or the interconnect structure 118. Additionally, the barrier layer 112 may be positioned between the interconnect structure 118 and the metal line 110 and/or between the interconnect structure 118 and the etch stop layer 106. For example, the barrier layer 112 may be in contact with the etch stop layer 106 and/or the metal line 110 (e.g., a capping layer of the metal line 110).

A zoomed in view of the barrier layer 112 is depicted and designated 140. The barrier layer 112 may include a composite of two or more metals, such as a first metal 114 and a second metal 116. In some implementations, the barrier layer 112 is a single layer. Each of the metals of the two or more metals may be phase segregated from each other metal included in the two or more metals. For example, each metal of the barrier layer 112 may not be dissolved into the other metal(s) of the barrier layer 112 (e.g., the metals of the barrier layer 112 are not combined as an alloy). To illustrate, the first metal 114 and the second metal 116 may be separate and not combined to form an alloy. Additionally, each metal of the barrier layer 112 may not dissolve into the conductive material (e.g., copper (Cu)) of the interconnect structure 118. For example, each metal of the two or more metals (e.g., the first metal 114 and the second metal 116) may be phase segregated from the conductive material. Each metal of the two or more metals (e.g., the first metal 114 and the second metal 116) of the barrier layer 112 may be different than the conductive material of the interconnect structure 118.

The barrier layer 112 may include a first concentration of the first metal 114 and a second concentration of the second metal 116. When the first concentration is greater than the second concentration, the first metal 114 may be considered a “major” metal component of the barrier layer 112 and the second metal 116 may be considered a “minor” metal component of the barrier layer 112. The barrier layer 112 may include one major metal component and one or more minor metal components. The second metal 116 may fill in gaps (e.g., spaces) between atoms of the first metal 114 to form a continuous barrier layer 112 that resists diffusion of a conductive material of the interconnect structure 118 into a dielectric material of the first dielectric layer 104. For example, the first metal 114 may have grains (e.g., channels) that are stuffed with the second metal 116. Stated another way, the second metal 116 (e.g., atoms of the second metal 116) may be segregated into grain boundaries of the first metal 114, such as gaps between atoms of the first metal 114.

The barrier layer 112 may have a thickness (t1) that may be less than or equal to 2 nanometers (nm). In some implementations the thickness (t1) may be within a range of 0.2 nm to 2 nm. For example, the thickness (t1) may be as thin as an atomic diameter of a particular metal of the two or more metals of the barrier layer 112. To illustrate, the particular metal may be determined to be a particular metal, of the two or more metals, that has a largest atomic diameter. Although the thickness (t1) of the barrier layer 112 is described as being less than or equal to 2 nm, in other implementations, the thickness (t1) may be greater than 2 nm.

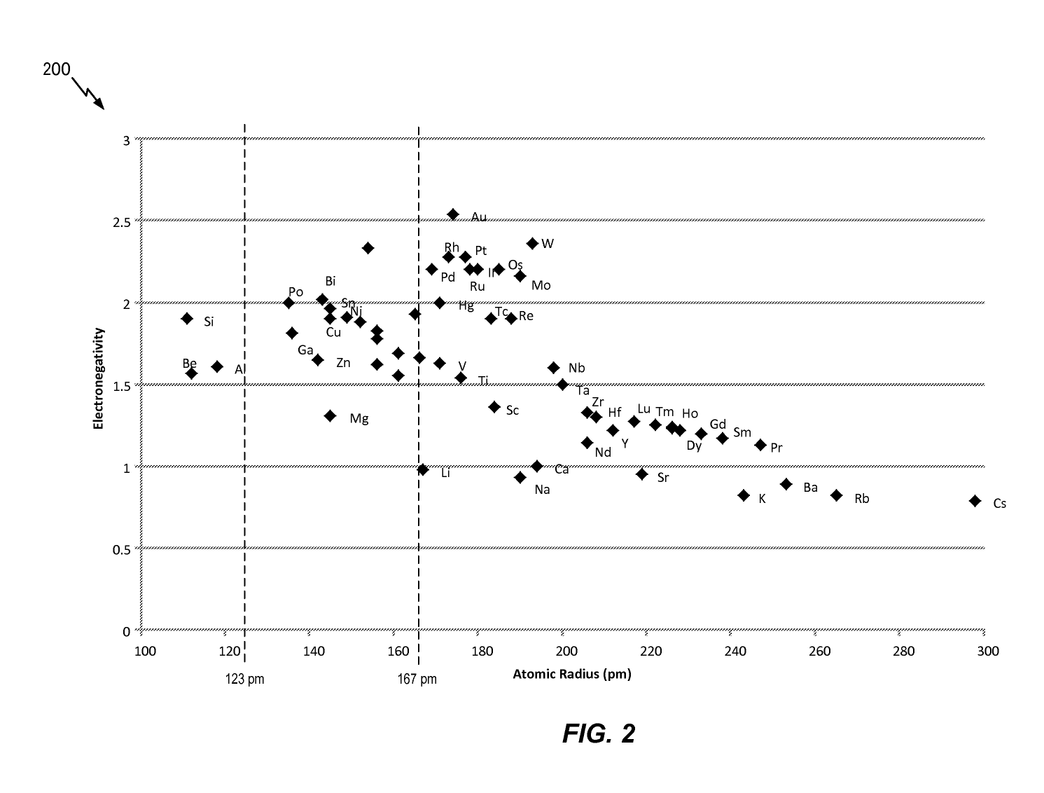

Each of the two or more metals of the barrier layer 112 may have low solubility with the other metal(s) of the barrier layer 112. Two metals may be considered to have low solubility if their atomic sizes (e.g., atomic diameter or atomic radius) differ by more than 15% percent. For example, when the first metal 114 has a first atomic diameter and the second metal 116 has a second atomic diameter, the second atomic diameter is not included within a range of ±15% of the first atomic diameter (e.g., a range between a first value=(0.85)*(the first atomic diameter) and a second value=(1.15)*(the first atomic diameter)), as further described with reference to FIG. 2. In other implementations, each of the two or more metals of the barrier layer 112 may have corresponding atomic sizes (e.g., atomic diameter or atomic radius) that do not differ by more than 15% (e.g., that differ by an amount less than or equal to 15%).

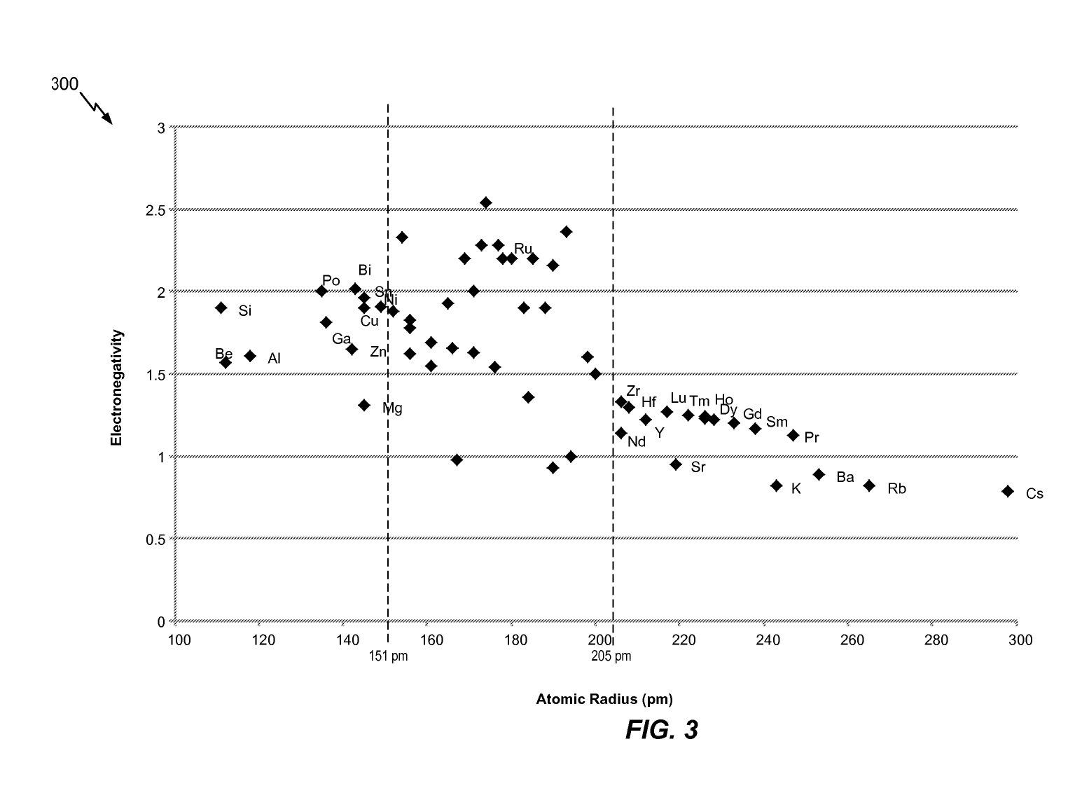

One or more of the two metals of the barrier layer 112 may have low solubility with the conductive material (e.g., copper (Cu)) of the interconnect structure 118. By having low solubility with the conductive material, the one or more metals may have good wettability with the conductive material and, thus, a seed layer may not be needed to be deposited on the barrier layer 112 prior to depositing the conductive material of the interconnect structure 118 (e.g., the conductive material may be deposited onto the barrier layer 112). A particular metal may be considered to have low solubility with the conductive material if an atomic size (e.g., atomic diameter or atomic radius) of the conductive metal and an atomic size (e.g., atomic diameter or atomic radius) of the conductive material differ by more than 15% percent. For example, when the conductive material (e.g., copper (Cu)) of the interconnect structure 118 has a particular atomic radius, the first metal 114 and the second metal 116 may each have an atomic radius that is outside of a range of ±15% of a particular atomic radius of a conductive material of the interconnect structure 118 (e.g., a range between a first value=(0.85)*(the particular atomic radius) and a second value=(1.15)*(the particular atomic radius)), as further described with reference to FIG. 3. In other implementations, the first metal 114 and/or the second metal 116 may have a corresponding atomic radius that is within the range of ±15% of a particular atomic radius of a conductive material of the interconnect structure 118.

In some implementations, the first metal 114 may include ruthenium (Ru) and the second metal 116 may include aluminum (Al), hafnium (Hf), zirconium (Zr), yttrium (Y), or niobium (Nd). In other implementations, the first metal 114 may include hafnium (Hf), zirconium (Zr), yttrium (Y), or niobium (Nd), and the second metal 116 may include ruthenium (Ru) or aluminum (Al). In additional implementations, the first metal 114 may include platinum (Pt), gold (Au), palladium (Pd), osmium (Os), ruthenium (Ru), rhodium (Rh), molybdenum (Mo), or iridium (Ir), and the second metal 116 may include aluminum (Al). When the barrier layer 112 comprises three or more metals, the three or more metals may include three or more of aluminum (Al), platinum (Pt), gold (Au), palladium (Pd), osmium (Os), ruthenium (Ru), rhodium (Rh), molybdenum (Mo), iridium (Ir), hafnium (Hf), zirconium (Zr), yttrium (Y), niobium (Nd), or a combination thereof.

During operation of the semiconductor device 100, one or more electrical charges (e.g., charges provided in response to an alternating current (AC) voltage or a direct current (DC) voltage from a signal/power source) may be applied to the interconnect structure 118. For example, a charge may be applied by a source, such as a signal/current source or a voltage source, at the metal line 110. The charge applied to the metal line 110 may pass through the interconnect structure 118 to another circuit coupled to the interconnect structure 118. As another example, the charge may be applied to the interconnect structure 118 and may pass through the interconnect structure 118 to the metal line 110. From the metal line 110, the charge may propagate to another circuit coupled to the metal line 110.

By having the barrier layer 112 include a composite of two or more metals, the barrier layer 112 may resist diffusion of a conductive material (e.g., copper (Cu)) of the interconnect structure 118 and may have good wettability (e.g., low solubility) with the conductive material. By having good wettability with the conductive material, a seed layer does not need to be applied to the barrier layer 112 prior to depositing the conductive material of the interconnect structure 118. In some implementations, the barrier layer 112 including the composite of the two or more metals may be ultra-thin (e.g., a thickness of the barrier layer 112 may be less than or equal to 2 nm). Additionally, the barrier layer 112 including the composite of two or more metals may be more conductive than a tantalum nitride (TaN)/tantalum (Ta) bi-layer barrier, which may reduce a total resistance of the barrier layer 112 and interconnect structure 118 as compared to a total resistance of an interconnect structure and a TaN/Ta bi-layer barrier.

Referring to FIG. 2, a graph 200 is depicted to illustrate selection of one or more metals having low solubility with copper (Cu). Copper (Cu) may be used as the conductive material included in the interconnect structure 118 of FIG. 1. The one or more metals may be selected to be included in the barrier layer 112 of FIG. 1. A metal to be used in a barrier layer, such as the barrier layer 112 of FIG. 1, may be selected that has low solubility with copper (Cu). By having low solubility with copper (Cu), the one or more metals may have good wettability with copper (Cu).

The metal may be considered to have low solubility with copper (Cu) if an atomic size (e.g., atomic diameter or atomic radius) of copper (Cu) and an atomic size (e.g., atomic diameter or atomic radius) of the metal differ by more than 15% percent. For example, the atomic radius of the metal may be outside of a range of ±15% of the atomic radius of copper (Cu) (e.g., a range between a first value=(0.85)*(the atomic radius of copper) and a second value=(1.15)*(the atomic radius of copper)). As illustrated in FIG. 2, a first value (e.g., a minimum value) of the range may be greater than or equal to 123 picometers (pm) and a second value (e.g., a maximum value) of the range may be less than or equal to 167 pm. Accordingly, one or more metals may be selected that have an atomic radius of less than or equal to 103 pm or that have an atomic radius of greater than or equal to 167 pm. To illustrate, metals that may have low solubility with copper (Cu) may include aluminum (Al), platinum (Pt), gold (Au), palladium (Pd), osmium (Os), ruthenium (Ru), rhodium (Rh), molybdenum (Mo), iridium (Ir), hafnium (Hf), zirconium (Zr), yttrium (Y), niobium (Nd), etc., as illustrative, non-limiting examples. A particular metal having low solubility with copper (Cu) may be selected to be used as the major metal component of the composite material of the barrier layer 112.

In some implementations, metals having similar electronegativity with copper (Cu) may be excluded from being selected. For example, technetium (Tc) may not be selected to be included in the barrier layer because technetium (Tc) and copper (Cu) have similar electronegativity values.

By identifying metals that have low solubility with copper (Cu), one or more metals may be selected to be included in the barrier layer, such as the barrier layer 112 of FIG. 1. The one or more metals having low solubility with copper (Cu) may enable copper (Cu) to be directly plated onto the barrier layer of the one or more metals without having to use a seed layer.

Referring to FIG. 3, a graph 300 is depicted to illustrate selection of metals included in a barrier layer. The barrier layer may include or correspond to the barrier layer 112 of FIG. 1. The barrier layer may be configured to resist diffusion of a conductive material (e.g., copper (Cu)) of an interconnect structure, such as the interconnect structure 118 of FIG. 1, into a dielectric material. As depicted in FIG. 3, ruthenium (Ru) has been selected to be a first metal, such as the first metal 114, included in the barrier layer. In some implementations, ruthenium (Ru) may be the major metal component of the barrier layer.

One or more metals may be selected to be used along with ruthenium (Ru) in the barrier layer. Each of the one or more metals may have a low solubility with ruthenium (Ru). A metal may be considered to have low solubility with ruthenium (Ru) if an atomic size (e.g., atomic diameter or atomic radius) of ruthenium (Ru) and an atomic size (e.g., atomic diameter or atomic radius) of the metal differ by more than 15% percent. For example, the atomic radius of the metal may be outside of a range of ±15% of the atomic radius of ruthenium (Ru) (e.g., a range between a first value=(0.85)*(the atomic radius of ruthenium) and a second value=(1.15)*(the atomic radius of ruthenium)). As illustrated in FIG. 3, a first value (e.g., a minimum value) of the range may be greater than or equal to 151 picometers (pm) and a second value (e.g., a maximum value) of the range may be less than or equal to 205 pm. Accordingly, one or more metals may be selected that have an atomic radius of less than or equal to 151 pm or that have an atomic radius of greater than or equal to 205 pm. To illustrate, metals that may have low solubility with ruthenium (Ru) may include aluminum (Al), hafnium (Hf), zirconium (Zr), yttrium (Y), niobium (Nd), etc., as illustrative, non-limiting examples. In some implementations, metals having similar electronegativity with ruthenium (Ru) may be excluded from being selected.

In some implementations, metals having similar electronegativity with the conductive material (e.g., copper) of the interconnect structure (e.g., the interconnect structure 118 of FIG. 1) may be excluded from being selected to be used along with ruthenium (Ru) in the barrier layer. For example, nickel (Ni) may have an atomic radius that is less than 151 pm, but, when the conductive material is copper (Cu), nickel (Ni) may not be selected to be used with ruthenium (Ru) because nickel (Ni) and copper (Cu) have similar electronegativity values.

By identifying metals that have low solubility with each other, a set of two or more metals to be included in a barrier layer may be selected. At least one of the two or more metals may have low solubility with a conductive material, such as copper (Cu), of an interconnect structure to enable the conductive material to be directly plated onto the barrier layer without having to use a seed layer.

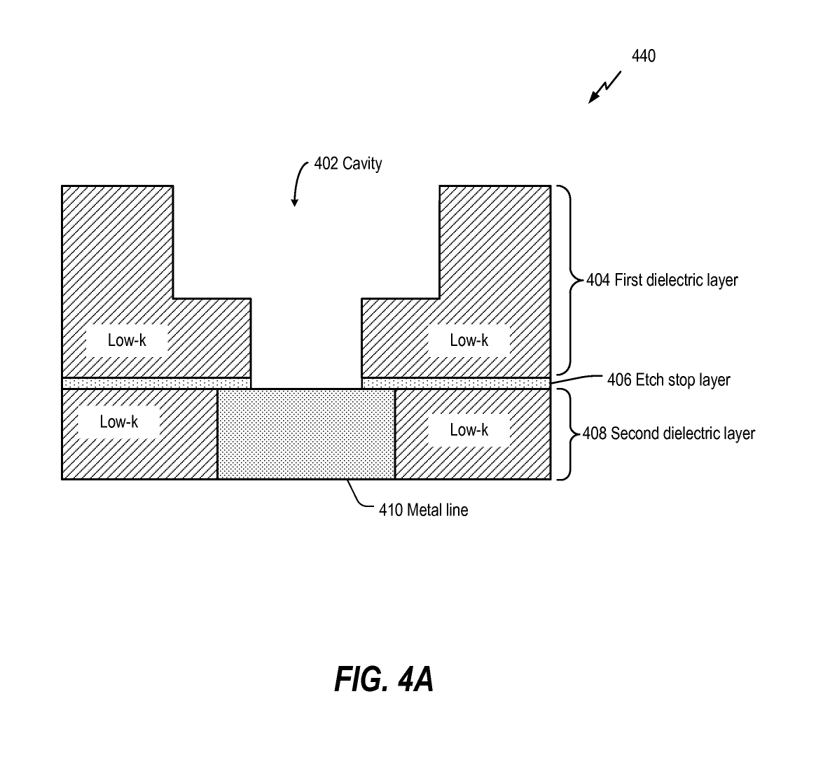

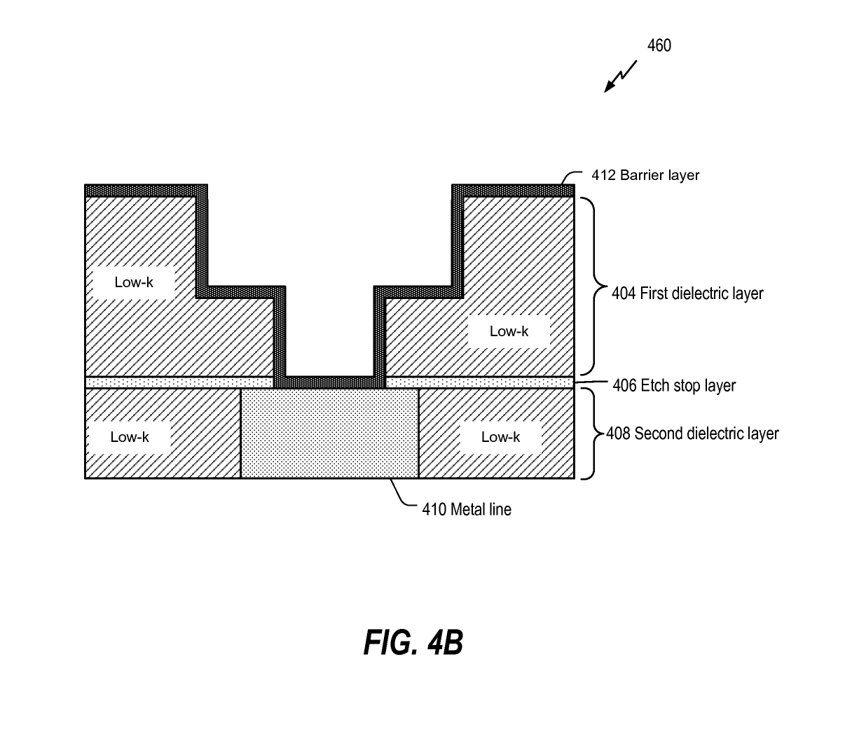

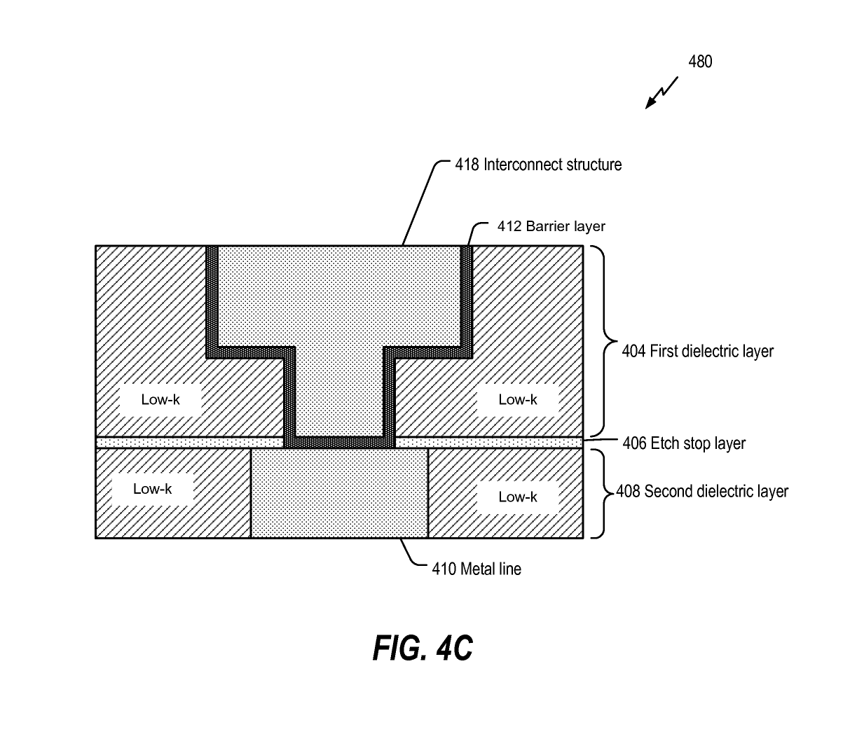

FIGS. 4A-4C illustrate examples of stages of a fabrication process that may be used to fabricate a barrier layer associated with an interconnect structure. The interconnect structure may be included in a wafer that is processed to fabricate (e.g., form) one or more semiconductor devices. The barrier layer and the interconnect structure may include or correspond to the barrier layer 112 and the interconnect structure 118 of FIG. 1, respectively.

Referring to FIG. 4A, a first stage of the fabrication process is depicted and generally designated 440. FIG. 4A shows a first dielectric layer 404, an etch stop layer 406, a second dielectric layer 408, and a metal line 410. The first dielectric layer 404, the etch stop layer 406, the second dielectric layer 408, and the metal line 410 may include or correspond to the first dielectric layer 104, the etch stop layer 106, the second dielectric layer 108, and the metal line 110 of FIG. 1, respectively. A cavity 402 may be formed within the first dielectric layer 404. For example, the cavity 402 may have been formed by performing one or more etches to remove portions of the first dielectric layer 404, the etch stop layer 406, and/or the second dielectric layer 408. Although the cavity 402 is illustrated as having a dual damascene structure, in other implementations, the cavity 402 may have another structure (e.g., another shape). The cavity 402 may extend through the first dielectric layer 404 and the etch stop layer 406 to expose a surface of the metal line 410. The metal line 410 may include a conductive material, such as copper (Cu), tungsten (W), cobalt (Co), or a combination thereof, as illustrative, non-limiting examples. In some implementations, the metal line 410 may include a barrier and/or capping material (e.g., a barrier layer, such as TaN/Ta, titanium nitride (TiN), or a composite material, as described herein, or a capping layer), and a conductive material, and the cavity 402 may expose a surface of the capping material.

Referring to FIG. 4B, a second stage of the fabrication process is depicted and generally designated 460. In FIG. 4B, a barrier layer 412 is formed in the cavity 402 of FIG. 4A. The barrier layer 412 may include or correspond to the barrier layer 112 of FIG. 1. The barrier layer 412 may have a thickness that is less than or equal to 2 nm. The barrier layer 412 may include a composite of two or more metals, such as a first metal and a second metal. For example, the first metal and the second metal may include or correspond to the first metal 114 and the second metal 116 of FIG. 1, respectively. The first metal and the second metal may be selected such that the first metal and the second metal do not dissolve into each other. Additionally, each of the first metal and the second metal may not dissolve into copper. At least one metal of the two or more metals may have low solubility with a conductive material (e.g., copper (Cu)) that may be included in an interconnect structure, such as the interconnect structure 118 of FIG. 1. Accordingly, the at least one metal may have good wettability with the conductive material, such as copper (Cu). During a processing window (e.g., a time period) to form the barrier layer 412, environmental conditions (e.g., temperature, pressure, etc.) experienced by the barrier layer 412 may be maintained such that the first metal and the second metal do not form an alloy.

As a first example of forming the barrier layer 412, the first metal may be deposited within the cavity 402 using a chemical vapor deposition (CVD) process or an atomic layer deposition (ALD) process. In some implementations, the first metal may be deposited to form a layer with a thickness of an atomic diameter of the first metal. After the first metal is deposited, the second metal may be deposited using the CVD process or the ALD process. After the first metal and the second metal are deposited, a thermal anneal may be performed on the first metal and the second metal to form the barrier layer 412, such as a single barrier layer. The thermal anneal may be a low temperature thermal anneal (e.g., an anneal having a low thermal budget), such that the first metal and the second metal do not form an alloy. For example, the thermal anneal may use a temperature of less than 400 degrees Celsius. The thermal anneal may enable atoms of the second metal to segregate and fill in gaps (e.g., spaces) between atoms of the first metal.

As a second example of forming the barrier layer 412, a composite material including the first metal and the second metal may be deposited (e.g., the first metal and the second metal may be deposited concurrently). A thermal anneal may be performed on the composite material to form the barrier layer 412. The thermal anneal may be a low temperature thermal anneal as described above.

In implementations in which the barrier layer 412 includes three or more metals, the three or more metals may be deposited concurrently or may be deposited sequentially (e.g., one after the other). After the three or more metals are deposited, the three or more metals may be thermally annealed. The thermal anneal may be a low temperature thermal anneal (e.g., an anneal having a low thermal budget), such that the metals of the three or more metals do not form one or more alloys.

Referring to FIG. 4C, a third stage of the first fabrication process is depicted and generally designated 480. FIG. 4C shows the semiconductor device after formation of the interconnect structure 418. The interconnect structure 418 may include or correspond to the interconnection structure 118 of FIG. 1. The interconnect structure 418 may include a conductive material, such as copper (Cu). In some implementations, a thickness of the barrier layer 412 positioned between a bottom portion of the interconnect structure 418 and the metal line 110 may not exceed 2 nm.

To form the interconnect structure 418, the conductive material may be deposited after the barrier layer 412 is formed, such as after the thermal anneal is performed. For example, the conductive material may be formed (e.g., by electrochemical plating) on the barrier layer 212 (e.g., the interconnect structure 418 may be in contact with the barrier layer 412). In some implementations, after the conductive material is deposited, thermal annealing may be performed and then a chemical mechanical planarization (CMP) process may be performed to remove portions of the barrier layer 412 and the conductive material that are above the first dielectric layer 104. Completion of the CMP process may result in the barrier layer 412 (e.g., a barrier structure) and the interconnect structure 418 as depicted in FIG. 4C.

After a barrier layer processing window to form the barrier layer 412, as described with reference to FIG. 4B, a wafer including the barrier layer 412 may be further processed such that the first metal and the second metal remain phase segregated (e.g., stable). For example, environmental conditions (e.g., temperature, pressure, etc.) during a back end-of-line processing window of the wafer performed after formation of the barrier layer 412 and/or after formation of the interconnect structure 418 may not cause the metals of the barrier layer and/or the conductive material to form one or more alloys.

The barrier layer 412 may resist diffusion of a conductive material (e.g., copper (Cu)) of the interconnect structure 418 and may have good wettability (e.g., low solubility) with the conductive material. By having good wettability with the conductive material, a seed layer does not need to be applied to the barrier layer 412 prior to depositing the conductive material of the interconnect structure 418. Additionally, the barrier layer 412 including the composite of two or more metals may be more conductive than a tantalum nitride (TaN)/tantalum (Ta) bi-layer barrier, which may reduce a total resistance of the barrier layer 412 and interconnect structure 418 as compared to a total resistance of an interconnect structure and a TaN/Ta bi-layer barrier.

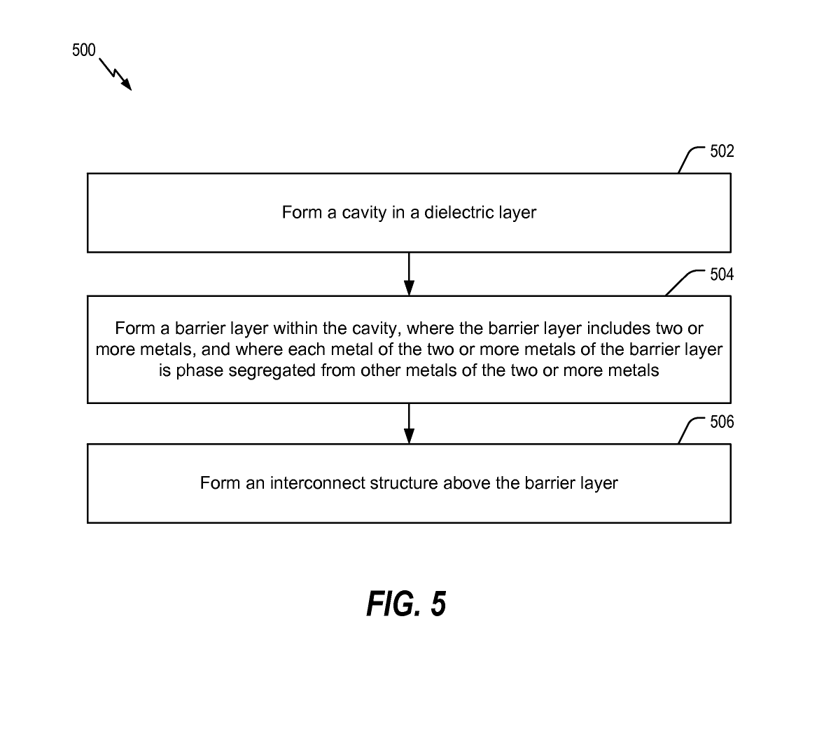

Referring to FIG. 5, a flow diagram of an illustrative embodiment of a method 500 of forming a semiconductor device is depicted and generally designated 500. The semiconductor device may include or correspond to the semiconductor device 100 of FIG. 1. The semiconductor device may include a barrier layer, such as the barrier layer 112 of FIG. 1 or the barrier layer 412 formed according to the process shown in FIGS. 4A-4C.

The method 500 may include forming a cavity in a dielectric layer, at 502. The dielectric layer may include or correspond to the dielectric layer 104 of FIG. 1 or the dielectric layer 404 as depicted in FIGS. 4A-4C. The cavity may be formed by performing one or more etches to remove portions of a first dielectric layer, an etch stop layer, and/or a second dielectric layer. With reference to FIG. 1, the first dielectric layer, the etch stop layer, and the second dielectric layer may correspond to the first dielectric layer 104, the etch stop layer 106, and the second dielectric layer 108, respectively. The cavity may include or correspond to the cavity 402 of FIG. 4A. In some implementations, the cavity may be associated with a dual damascene structure. In other implementations, the cavity may be associated with a structure other than a dual damascene structure.

The method 500 may further include forming a barrier layer within the cavity, at 504. The barrier layer may include two or more metals. Each metal of the two or more metals of the barrier layer is phase segregated from each other metal of the two or more metals. For example, the two or more metals may not be bonded to form a metal alloy (e.g., each metal of the two or more metals may remain phase segregated to each other metal of the two or more metals). For example, the barrier layer may include or correspond to the barrier layer 112 of FIG. 1 or the barrier layer 412 of FIGS. 4B and 4C. In some implementations, the two or more metals may include a first metal and a second metal. The first metal and the second metal may include or correspond to the first metal 114 and the second metal 116 of FIG. 1, respectively. The first metal may be a major metal component of the barrier material. The barrier layer may have a thickness of less than or equal to 2 nanometers (nm).

The method 500 may further include forming an interconnect structure above the barrier layer, at 506. For example, the interconnect structure may include or correspond to the interconnect structure 118 of FIG. 1 or the interconnect structure 418 of FIG. 4. The interconnect structure may include a conductive material, such as copper (Cu). In some implementations, forming the interconnect structure may include depositing copper on the barrier layer and performing a chemical mechanical planarization (CMP) process on the copper and on the barrier layer to form the interconnect structure. For example, the interconnect structure may be in contact with the barrier layer.

In some implementations, forming the barrier layer may include depositing a composite barrier material. The composite barrier material may include the first metal and the second metal. For example, the first metal and the second metal may be concurrently deposited within the cavity. After deposition of the composite barrier material, a thermal anneal may be performed on the composite barrier material to form the barrier layer. For example, the thermal anneal may be a low temperature thermal anneal.

In other implementations, forming the barrier layer may include depositing the first metal using a chemical vapor deposition (CVD) process or an atomic layer deposition (ALD) process. After the first metal is deposited, the second metal may be deposited using the CVD process or the ALD process. A thermal anneal may be performed on the first metal and the second metal to form the barrier layer. Although the first metal has been described as being deposited prior to the second metal, in other implementations, the first metal may be deposited after the second metal is deposited.

The method 500 may be used to form a barrier layer that includes a composite of two or more metals. The barrier layer may have a thickness of less than or equal to 2 nm and may be configured to resist diffusion of a conductive material (e.g., copper (Cu)) of the interconnect structure to a dielectric material of the dielectric layer. Additionally, the barrier layer including the composite of two or more metals may be more conductive than a tantalum nitride (TaN)/tantalum (Ta) bi-layer barrier, which may reduce a total resistance of the barrier layer 112 and interconnect structure 118 as compared to a total resistance of an interconnect structure and a TaN/Ta bi-layer barrier.

The process shown in FIGS. 4A-4C and/or the method 500 of FIG. 5 may be controlled by a processing unit such as a central processing unit (CPU), a controller, a field-programmable gate array (FPGA) device, an application-specific integrated circuit (ASIC), another hardware device, firmware device, or any combination thereof. As an example, the process shown in FIGS. 4A-4C and/or the method 500 of FIG. 5 can be performed by one or more processors that execute instructions to control fabrication equipment.

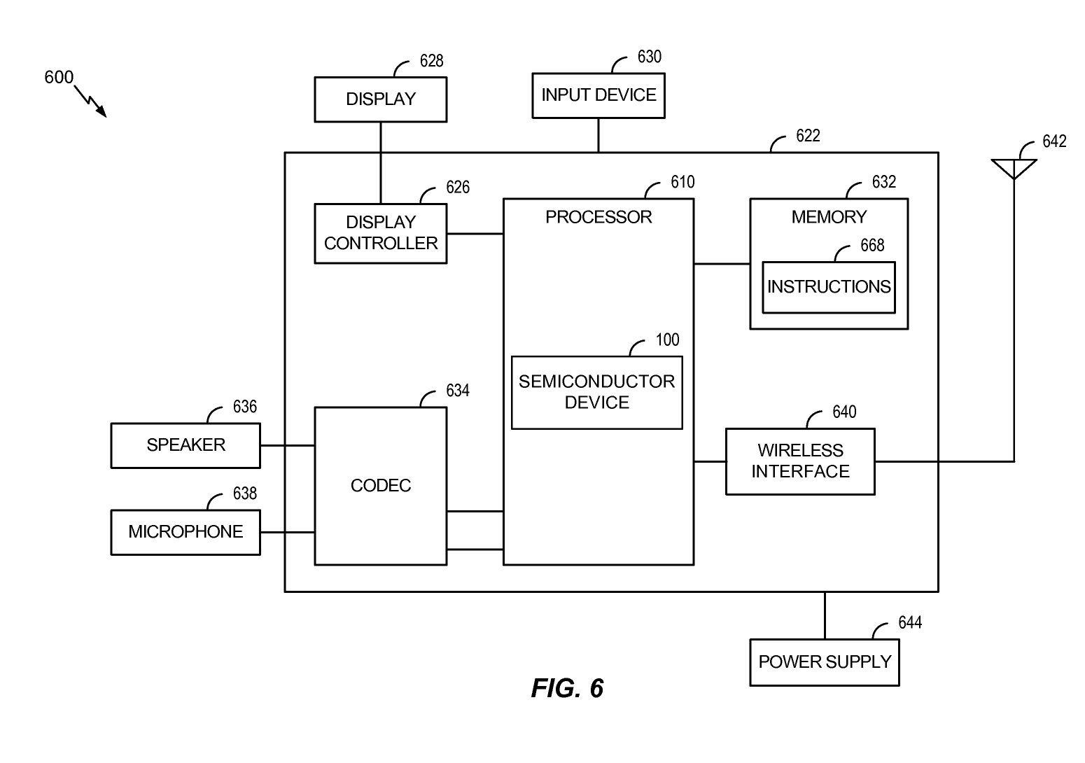

Referring to FIG. 6, a block diagram of a particular illustrative embodiment of an electronic device 600, such as a wireless communication device, is depicted. The device 600 includes a processor 610, such as a digital signal processor (DSP), coupled to a memory 632. The processor 610, or components thereof, may include the semiconductor device 100 of FIG. 1. To illustrate, the processor 610 may be constructed in such a way that components of the processor 610 may be electrically connected to one or more structures, such as the metal line 110, the barrier layer 112, and/or the interconnect structure 118 of FIG. 1, that are included in the semiconductor device 100.

The memory 632 includes instructions 668 (e.g., executable instructions), such as computer-readable instructions or processor-readable instructions. The instructions 668 may include one or more instructions that are executable by a computer, such as the processor 610.

FIG. 6 also shows a display controller 626 that is coupled to the processor 610 and to a display 628. A coder/decoder (CODEC) 634 can also be coupled to the processor 610. A speaker 636 and a microphone 638 can be coupled to the CODEC 634.

FIG. 6 also indicates that a wireless interface 640 can be coupled to the processor 610 and to an antenna 642. In some implementations, the semiconductor device 100, the processor 610, the display controller 626, the memory 632, the CODEC 634, and the wireless interface 640 are included in a system-in-package or system-on-chip device 622. In a particular embodiment, an input device 630 and a power supply 644 are coupled to the system-on-chip device 622. Moreover, in a particular embodiment, as illustrated in FIG. 6, the display 628, the input device 630, the speaker 636, the microphone 638, the antenna 642, and the power supply 644 are external to the system-on-chip device 622. However, each of the display 628, the input device 630, the speaker 636, the microphone 638, the antenna 642, and the power supply 644 can be coupled to a component of the system-on-chip device 622, such as an interface or a controller. Although the semiconductor device 100 is depicted as being included in the processor 610, in other implementations, the semiconductor device 100 may be included in another component of the device 600 or a component coupled to the device 600. For example, the semiconductor device 100 may be included in the memory 632, the wireless interface 640 (e.g., wireless controller), the power supply 644, the input device 630, the display 628, the display controller 626, the CODEC 634, the speaker 636, or the microphone 638. To illustrate, one or more of the components of the electronic device 600 may include a semiconductor device (e.g., the semiconductor device 100) that is constructed in such a way that components of the semiconductor device may be electrically connected by structures/interconnects (e.g., corresponding to the barrier layer 112 and the interconnect structure 118 of FIG. 1). The interconnects may be used to route power/signals between circuits of the semiconductor device.

In conjunction with one or more of the described embodiments of FIGS. 1-6, an apparatus is disclosed that may include means (e.g., a barrier layer) for resisting diffusion of a conductive material of an interconnect of a semiconductor device into a dielectric layer of a semiconductor device. The means for resisting diffusion may correspond to the barrier layer 112 of FIG. 1, the barrier layer 412 of FIGS. 4B-4C, one or more other structures configured to resist diffusion, or any combination thereof. The means for resisting diffusion may include two or more metals and each of the two or more metals of the means for resisting diffusion may be phase segregated from each other metal of the two or more metals. In some implementations, the means for resisting diffusion may be in contact with the dielectric layer and in contact with the conductive material.

The apparatus may also include means for conducting current coupled to the interconnect. The means for conducting current may correspond to the metal line 110 of FIG. 1, the metal line 410 of FIGS. 4A-4C, one or more other structures configured to conduct current, or any combination thereof. In some implementations, the means for resisting diffusion is positioned between the means for conducting current and the interconnect.

One or more of the disclosed embodiments may be implemented in a system or an apparatus, such as the electronic device 600, that may include a communications device, a fixed location data unit, a mobile location data unit, a mobile phone, a cellular phone, a satellite phone, a computer, a tablet, a portable computer, a display device, a media player, or a desktop computer. Alternatively or additionally, the electronic device 600 may include a set top box, an entertainment unit, a navigation device, a personal digital assistant (PDA), a monitor, a computer monitor, a television, a tuner, a radio, a satellite radio, a music player, a digital music player, a portable music player, a video player, a digital video player, a digital video disc (DVD) player, a portable digital video player, a satellite, a vehicle, any other device that includes a processor or that stores or retrieves data or computer instructions, or a combination thereof. As another illustrative, non-limiting example, the system or the apparatus may include remote units, such as hand-held personal communication systems (PCS) units, portable data units such as global positioning system (GPS) enabled devices, meter reading equipment, or any other device that includes a processor or that stores or retrieves data or computer instructions, or any combination thereof.

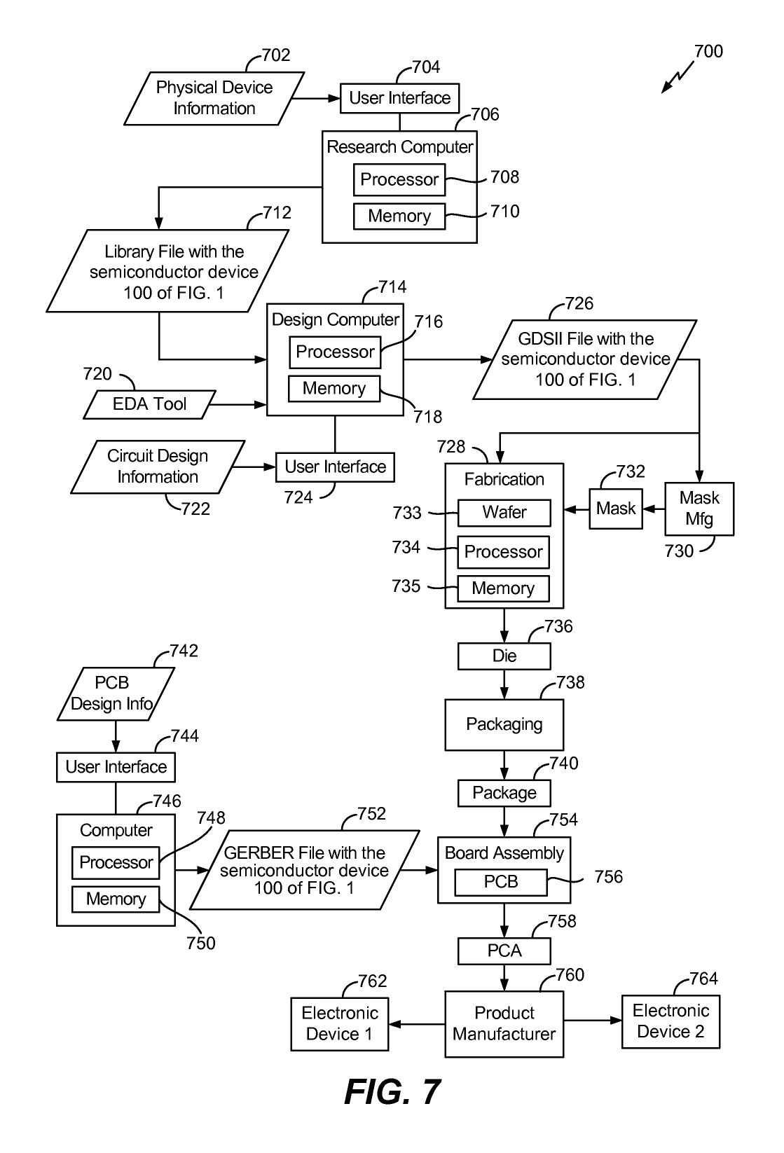

The foregoing disclosed devices and functionalities may be designed and configured into computer files (e.g. RTL, GDSII, GERBER, etc.) stored on computer-readable media. Some or all such files may be provided to fabrication handlers who fabricate devices based on such files. Resulting products include semiconductor wafers that are then cut into semiconductor die and packaged into a semiconductor chip. The chips are then employed in devices described above. FIG. 7 depicts a particular illustrative embodiment of an electronic device manufacturing process 700.

Physical device information 702 is received at the manufacturing process 700, such as at a research computer 706. The physical device information 702 may include design information representing at least one physical property of the semiconductor device 100 of FIG. 1, a semiconductor device formed according to the process shown in FIGS. 4A-4C, a semiconductor device formed according to the method 500 of FIG. 5, or a combination thereof. For example, the physical device information 702 may include physical parameters, material characteristics, and structure information that is entered via a user interface 704 coupled to the research computer 706. The research computer 706 includes a processor 708, such as one or more processing cores, coupled to a computer-readable medium (e.g., a non-transitory computer-readable medium), such as a memory 710. The memory 710 may store computer-readable instructions that are executable to cause the processor 708 to transform the physical device information 702 to comply with a file format and to generate a library file 712.

In some implementations, the library file 712 includes at least one data file including the transformed design information. For example, the library file 712 may include a library of devices including a device that includes the semiconductor device 100 of FIG. 1, a semiconductor device formed according to the process shown in FIGS. 4A-4C, a semiconductor device formed according to the method 500 of FIG. 5, or a combination thereof, that is provided for use with an electronic design automation (EDA) tool 720.

The library file 712 may be used in conjunction with the EDA tool 720 at a design computer 714 including a processor 716, such as one or more processing cores, coupled to a memory 718. The EDA tool 720 may be stored as processor executable instructions at the memory 718 to enable a user of the design computer 714 to design a circuit including the semiconductor device 100 (e.g., an interconnect including the barrier layer 112 and an interconnect structure, such as the interconnect structure 118) of FIG. 1, a semiconductor device (e.g., an interconnect including the barrier layer 412 and an interconnect structure, such as the interconnect structure 418) formed according to the process shown in FIGS. 4A-4C, a semiconductor device (e.g., an interconnect including a barrier layer and an interconnect structure) formed according to the method 500 of FIG. 5, or a combination thereof. For example, a user of the design computer 714 may enter circuit design information 722 via a user interface 724 coupled to the design computer 714. The circuit design information 722 may include design information representing at least one physical property of a component (e.g., a metal line, a barrier layer, or an interconnect structure) of the semiconductor device 100 of FIG. 1, a semiconductor device formed according to the process shown in FIGS. 4A-4C, a semiconductor device formed according to the method 500 of FIG. 5, or a combination thereof. To illustrate, the circuit design property may include identification of particular circuits and relationships to other elements in a circuit design, positioning information, feature size information, interconnection information, or other information representing a physical property of components (e.g., a metal line, a barrier layer, and/or an interconnect structure) of the semiconductor device 100 of FIG. 1, a semiconductor device formed according to the process shown in FIGS. 4A-4C, a semiconductor device formed according to the method 500 of FIG. 5.

The design computer 714 may be configured to transform the design information, including the circuit design information 722, to comply with a file format. To illustrate, the file format may include a database binary file format representing planar geometric shapes, text labels, and other information about a circuit layout in a hierarchical format, such as a Graphic Data System (GDSII) file format. The design computer 714 may be configured to generate a data file including the transformed design information, such as a GDSII file 726 that includes information describing the semiconductor device 100 of FIG. 1, a semiconductor device formed according to the process shown in FIGS. 4A-4C, a semiconductor device formed according to the method 500 of FIG. 5, or a combination thereof, in addition to other circuits or information. To illustrate, the data file may include information corresponding to a system-on-chip (SOC) that includes the semiconductor device 100 of FIG. 1, a semiconductor device formed according to the process shown in FIGS. 4A-4C, a semiconductor device formed according to the method 500 of FIG. 5, or a combination thereof, and that also includes additional electronic circuits and components within the SOC.

The GDSII file 726 may be received at a fabrication process 728 to manufacture the semiconductor device 100 of FIG. 1, a semiconductor device formed according to the process shown in FIGS. 4A-4C, a semiconductor device formed according to the method 500 of FIG. 5, or a combination thereof, according to transformed information in the GDSII file 726. For example, a device manufacture process may include providing the GDSII file 726 to a mask manufacturer 730 to create one or more masks, such as masks to be used with photolithography processing, illustrated as a representative mask 732. The mask 732 may be used during the fabrication process to generate one or more wafers 733, which may be tested and separated into dies, such as a representative die 736. The die 736 includes a circuit including a device that includes the semiconductor device 100 of FIG. 1, a semiconductor device formed according to the process shown in FIGS. 4A-4C, a semiconductor device formed according to the method 500 of FIG. 5, or a combination thereof.

For example, the fabrication process 728 may include a processor 734 and a memory 735 to initiate and/or control the fabrication process 728. The memory 735 may include executable instructions such as computer-readable instructions or processor-readable instructions. The executable instructions may include one or more instructions that are executable by a computer such as the processor 734.

The fabrication process 728 may be implemented by a fabrication system that is fully automated or partially automated. For example, the fabrication process 728 may be automated according to a schedule. The fabrication system may include fabrication equipment (e.g., processing tools) to perform one or more operations to form a semiconductor device, such as the semiconductor device 100 of FIG. 1, a semiconductor device formed according to the process shown in FIGS. 4A-4C, a semiconductor device formed according to the method 500 of FIG. 5, or a combination thereof. For example, the fabrication equipment may be configured to deposit one or more materials, etch one or more materials, etch one or more dielectric materials, etch one or more etch stop layers, perform a chemical mechanical planarization process, deposit a composite barrier material, perform a thermal anneal, deposit a conductive material, perform a chemical vapor deposition (CVD) process, perform an atomic layer deposition (ALD) process, etc., or a combination thereof, as illustrative, non-limiting examples.

The fabrication system (e.g., an automated system that performs the fabrication process 728) may have a distributed architecture (e.g., a hierarchy). For example, the fabrication system may include one or more processors, such as the processor 734, one or more memories, such as the memory 735, and/or controllers that are distributed according to the distributed architecture. The distributed architecture may include a high-level processor that controls or initiates operations of one or more low-level systems. For example, a high-level portion of the fabrication process 728 may include one or more processors, such as the processor 734, and the low-level systems may each include or may be controlled by one or more corresponding controllers. A particular controller of a particular low-level system may receive one or more instructions (e.g., commands) from a particular high-level system, may issue sub-commands to subordinate modules or process tools, and may communicate status data back to the particular high-level. Each of the one or more low-level systems may be associated with one or more corresponding pieces of fabrication equipment (e.g., processing tools). In some implementations, the fabrication system may include multiple processors that are distributed in the fabrication system. For example, a controller of a low-level system component may include a processor, such as the processor 734.

Alternatively, the processor 734 may be a part of a high-level system, subsystem, or component of the fabrication system. In another implementation, the processor 734 includes distributed processing at various levels and components of a fabrication system.

Thus, the processor 734 may include processor-executable instructions that, when executed by the processor 734, cause the processor 734 to initiate or control formation of an interconnect. For example, the executable instructions included in the memory 735 may enable the processor 734 to initiate formation of the semiconductor device 100 (e.g., an interconnect including the barrier layer 112 and an interconnect structure, such as the interconnect structure 118) of FIG. 1, a semiconductor device (e.g., an interconnect including the barrier layer 412 and an interconnect structure, such as the interconnect structure 418) formed according to the process shown in FIGS. 4A-4C, a semiconductor device (e.g., an interconnect including a barrier layer and an interconnect structure) formed according to the method 500 of FIG. 5, or a combination thereof. In some implementations, the memory 735 is a non-transient computer-readable medium storing computer-executable instructions that are executable by the processor 734 to cause the processor 734 to initiate formation of a semiconductor device in accordance with at least a portion of the process shown in FIGS. 4A-4C, at least a portion of the method 500 of FIG. 5, or any combination thereof. For example, the computer executable instructions may be executable to cause the processor 734 to initiate or control formation of the semiconductor device 100 of FIG. 1.

As an illustrative example, the processor 734 may initiate or control forming a cavity in a dielectric layer of a semiconductor device. The processor 734 may further initiate or control forming a barrier layer within the cavity. The barrier layer may include a first metal and a second metal, and the barrier layer may have a thickness of less than or equal to 2 nanometers (nm). The processor 734 may further initiate or control forming an interconnect structure above the barrier layer.

The die 736 may be provided to a packaging process 738 where the die 736 is incorporated into a representative package 740. For example, the package 740 may include the single die 736 or multiple dies, such as a system-in-package (SiP) arrangement. For example, the package 740 may include or correspond to the system in package or system-on-chip device 622 of FIG. 6. The package 740 may be configured to conform to one or more standards or specifications, such as Joint Electron Device Engineering Council (JEDEC) standards.

Information regarding the package 740 may be distributed to various product designers, such as via a component library stored at a computer 746. The computer 746 may include a processor 748, such as one or more processing cores, coupled to a memory 750. A printed circuit board (PCB) tool may be stored as processor executable instructions at the memory 750 to process PCB design information 742 received from a user of the computer 746 via a user interface 744. The PCB design information 742 may include physical positioning information of a packaged semiconductor device on a circuit board, the packaged semiconductor device including the semiconductor device 100 of FIG. 1, a semiconductor device formed according to the process shown in FIGS. 4A-4C, a semiconductor device formed according to the method 500 of FIG. 5, or a combination thereof.

The computer 746 may be configured to transform the PCB design information 742 to generate a data file, such as a GERBER file 752 with data that includes physical positioning information of a packaged semiconductor device on a circuit board, as well as layout of electrical connections such as traces (e.g., metal lines) and vias (e.g., via structures), where the packaged semiconductor device corresponds to the package 740 including the semiconductor device 100 of FIG. 1, a semiconductor device formed according to the process shown in FIGS. 4A-4C, a semiconductor device formed according to the method 500 of FIG. 5, or a combination thereof. In other implementations, the data file generated by the transformed PCB design information may have a format other than a GERBER format.

The GERBER file 752 may be received at a board assembly process 754 and used to create PCBs, such as a representative PCB 756, manufactured in accordance with the design information stored within the GERBER file 752. For example, the GERBER file 752 may be uploaded to one or more machines to perform various steps of a PCB production process. The PCB 756 may be populated with electronic components including the package 740 to form a representative printed circuit assembly (PCA) 758.

The PCA 758 may be received at a product manufacture process 760 and integrated into one or more electronic devices, such as a first representative electronic device 762 and a second representative electronic device 764. For example, the first representative electronic device 762, the second representative electronic device 764, or both, may include or correspond to the device 600 of FIG. 6. As an illustrative, non-limiting example, the first representative electronic device 762, the second representative electronic device 764, or both, may include a communications device, a fixed location data unit, a mobile location data unit, a mobile phone, a cellular phone, a satellite phone, a computer, a tablet, a portable computer, or a desktop computer, into which the semiconductor device 100 (e.g., a dielectric material and an interconnect including the barrier layer 112 and an interconnect structure, such as the interconnect structure 118) of FIG. 1, a semiconductor device (e.g., a dielectric material and an interconnect including the barrier layer 412 and an interconnect structure, such as the interconnect structure 418) formed according to the process shown in FIGS. 4A-4C, a semiconductor device (e.g., a dielectric material and an interconnect including a barrier layer and an interconnect structure) formed according to the method 500 of FIG. 5, or a combination thereof, is integrated. Alternatively or additionally, the first representative electronic device 762, the second representative electronic device 764, or both, may include a set top box, an entertainment unit, a navigation device, a personal digital assistant (PDA), a monitor, a computer monitor, a television, a tuner, a radio, a satellite radio, a music player, a digital music player, a portable music player, a video player, a digital video player, a digital video disc (DVD) player, a portable digital video player, any other device that includes a processor or that stores or retrieves data or computer instructions, or a combination thereof, into which the semiconductor device 100 (e.g., a dielectric material and an interconnect including the barrier layer 112 and an interconnect structure, such as the interconnect structure 118) of FIG. 1, a semiconductor device (e.g., a dielectric material and an interconnect including the barrier layer 412 and an interconnect structure, such as the interconnect structure 418) formed according to the process shown in FIGS. 4A-4C, a semiconductor device (e.g., a dielectric material and an interconnect including a barrier layer and an interconnect structure) formed according to the method 500 of FIG. 5, or a combination thereof, is integrated. As another illustrative, non-limiting example, one or more of the electronic devices 762 and 764 may include remote units, such as mobile phones, hand-held personal communication systems (PCS) units, portable data units such as personal data assistants, global positioning system (GPS) enabled devices, navigation devices, fixed location data units such as meter reading equipment, any other device that includes a processor or that stores or retrieves data or computer instructions, or any combination thereof. Although FIG. 7 illustrates remote units according to teachings of the disclosure, the disclosure is not limited to these illustrated units. Embodiments of the disclosure may be suitably employed in any device which includes active integrated circuitry including memory and on-chip circuitry.

A device that includes the semiconductor device 100 of FIG. 1, a semiconductor device formed according to the process shown in FIGS. 4A-4C, a semiconductor device formed according to the method 500 of FIG. 5, or a combination thereof, may be fabricated, processed, and incorporated into an electronic device, as described in the illustrative process 700. One or more aspects of the embodiments disclosed with respect to FIGS. 1-7 may be included at various processing stages, such as within the library file 712, the GDSII file 726 (e.g., a file having a GDSII format), and the GERBER file 752 (e.g., a file having a GERBER format), as well as stored at the memory 710 of the research computer 706, the memory 718 of the design computer 714, the memory 750 of the computer 746, the memory of one or more other computers or processors (not shown) used at the various stages, such as at the board assembly process 754, and also incorporated into one or more other physical embodiments such as the mask 732, the die 736, the package 740, the PCA 758, other products such as prototype circuits or devices (not shown), or any combination thereof. Although various representative stages of production from a physical device design to a final product are depicted, in other embodiments fewer stages may be used or additional stages may be included. Similarly, the process 700 may be performed by a single entity or by one or more entities performing various stages of the process 700.

Although one or more of FIGS. 1-7 may illustrate systems, apparatuses, and/or methods according to the teachings of the disclosure, the disclosure is not limited to these illustrated systems, apparatuses, and/or methods. One or more functions or components of any of FIGS. 1-7 as illustrated or described herein may be combined with one or more other portions of another of FIGS. 1-7. Accordingly, no single embodiment described herein should be construed as limiting and embodiments of the disclosure may be suitably combined without departing from the teachings of the disclosure.

Those of skill would further appreciate that the various illustrative logical blocks, configurations, modules, circuits, and algorithm steps described in connection with the embodiments disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. For example, a storage medium may be coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

What is claimed is:

1. A semiconductor device comprising:
a dielectric material;
an interconnect structure; and
a barrier layer positioned between the dielectric material and the interconnect structure, wherein the barrier layer comprises two or more metals, and wherein each metal of the two or more metals of the barrier layer is phase segregated from each other metal of the two or more metals.

2. The semiconductor device of claim 1, wherein the dielectric material includes a low-k dielectric material, and wherein the interconnect structure comprises copper.

3. The semiconductor device of claim 1, wherein the interconnect structure is in contact with the barrier layer, and wherein the barrier layer is in contact with the dielectric material.

4. The semiconductor device of claim 1, wherein the barrier layer is a single layer that includes the two or more metals, and wherein the barrier layer has a thickness of less than or equal to 2 nanometers (nm).

5. The semiconductor device of claim 4, wherein at least one metal of the two or more metals has low solubility with a conductive material of the interconnect structure.

6. The semiconductor device of claim 4, wherein a conductive material of the interconnect structure has a particular atomic radius, and wherein each metal of the two or more metals has a corresponding atomic radius that is outside of a range of ±15% of the particular atomic radius.

7. The semiconductor device of claim 1, wherein the barrier layer comprises a first metal and a second metal.

8. The semiconductor device of claim 7, wherein the barrier layer includes a first concentration of the first metal and a second concentration of the second metal, and wherein the first concentration is greater than the second concentration.

9. The semiconductor device of claim 7, wherein the barrier layer does not include an alloy of the first metal and the second metal.

10. The semiconductor device of claim 7, wherein the first metal and the second metal do not dissolve into copper.

11. The semiconductor device of claim 7, wherein the first metal has a first atomic diameter, wherein the second metal has a second atomic diameter, and wherein the second atomic diameter is not included within a range of ±15% of the first atomic diameter.

12. The semiconductor device of claim 7, wherein the first metal includes ruthenium (Ru), and wherein the second metal includes aluminum (Al), hafnium (Hf), zirconium (Zr), yttrium (Y), or niobium (Nd).

13. The semiconductor device of claim 7, wherein the first metal includes hafnium (Hf), zirconium (Zr), yttrium (Y), or niobium (Nd), and wherein the second metal include ruthenium (Ru) or aluminum (Al).

14. The semiconductor device of claim 7, wherein the first metal includes platinum (Pt), gold (Au), palladium (Pd), osmium (Os), ruthenium (Ru), rhodium (Rh), molybdenum (Mo), or iridium (Ir), and wherein the second metal includes aluminum (Al).

15. The semiconductor device of claim 1, wherein the barrier layer comprises three or more metals.

16. The semiconductor device of claim 15, wherein the three or more metals include three or more of aluminum (Al), platinum (Pt), gold (Au), palladium (Pd), osmium (Os), ruthenium (Ru), rhodium (Rh), molybdenum (Mo), iridium (Ir), hafnium (Hf), zirconium (Zr), yttrium (Y), niobium (Nd), or a combination thereof.

17. A method comprising:
forming a cavity in a dielectric layer;
forming a barrier layer within the cavity, wherein the barrier layer comprises two or more metals, and wherein each metal of the two or more metals of the barrier layer is phase segregated from each other metal of the two or more metals; and
forming an interconnect structure above the barrier layer.

18. The method of claim 17, wherein the cavity is associated with a dual damascene structure.

19. The method of claim 17, wherein forming the barrier layer comprises:
depositing a composite barrier material within the cavity, wherein the composite barrier material includes a first metal and a second metal, and wherein the first metal and the second metal are deposited concurrently; and
performing a thermal anneal on the composite barrier material to form the barrier layer.

20. The method of claim 17, wherein forming the barrier layer comprises:
depositing a first metal within the cavity using a chemical vapor deposition (CVD) process or an atomic layer deposition (ALD) process;
depositing a second metal within the cavity using the CVD process or the ALD process, the second metal deposited after the first metal, wherein the second metal segregates into grain boundaries associated with the first metal; and
performing a thermal anneal on the first metal and the second metal to form the barrier layer, wherein the barrier layer comprises a single layer that includes the first metal and the second metal.

21. The method of claim 17, wherein forming the interconnect structure comprises:
depositing copper on the barrier layer; and
performing a chemical mechanical planarization (CMP) process on the copper and on the barrier layer to form the interconnect structure.

22. The method of claim 17, wherein forming the cavity, forming the barrier layer, and forming the interconnect structure are initiated at or controlled by a controller of a fabrication system.

23. A computer-readable storage device that stores instructions that, when executed by a processor, cause the processor to perform operations including:
initiating formation of a cavity in a dielectric layer of a semiconductor device;
initiating formation of a barrier layer within the cavity, wherein the barrier layer comprises two or more metals, and wherein each metal of the two or more metals of the barrier layer is phase segregated from each other metal of the two or more metals; and
initiating formation of an interconnect structure above the barrier layer.

24. The computer-readable storage device of claim 23, wherein the barrier layer comprises a first metal and a second metal.

25. The computer-readable storage device of claim 23, wherein the barrier layer has a thickness of less than 2 nm.

26. The computer-readable storage device of claim 23, wherein a thickness of the barrier layer is within a range of 0.2-2.0 nm.

27. An apparatus comprising:
means for resisting diffusion of a conductive material of an interconnect of a semiconductor device into a dielectric layer of the semiconductor device, wherein the means for resisting comprises two or more metals, and wherein each metal of the two or more metals of the means for resisting diffusion is phase segregated from each other metal of the two or more metals; and
means for conducting current coupled to the interconnect, wherein the means for resisting diffusion is positioned between the means for conducting and the interconnect.

28. The apparatus of claim 27, wherein the means for resisting diffusion is in contact with the dielectric layer and in contact with the conductive material.

29. The apparatus of claim 27, wherein the means for resisting diffusion includes two or more metals, and wherein the means for conducting includes a metal line.

30. The apparatus of claim 27, wherein the means for resisting diffusion and the means for conducting current are integrated into at least one semiconductor device.
